(19) United States
(12) Patent Application Publication
(10) Pub. No.: US 2025/0377598 A1
(43) Pub. Date: Dec. 11, 2025

(54) METHODS, STRUCTURES, AND SYSTEMS FOR LITHOGRAPHIC PATTERNING

(71) Applicant: ASM IP Holding B.V., Almere (NL)

(72) Inventors: Kishan Ashokbhai Patel, Leuven (BE); Steaphan Mark Wallace, Tama City Tokyo (JP); Yoann Tomczak, Leuven (BE); Yiting Sun, Leuven (BE); David Kurt De Roest, Leuven (BE); Charles Dezelah, Helsinki (FI)

(21) Appl. No.: 19/231,663

(22) Filed: Jun. 9, 2025

Related U.S. Application Data
(60) Provisional application No. 63/658,684, filed on Jun. 11, 2024.

(51) Int. Cl. G03F 7/16; C23C 16/26; C23C 16/455; C23C 16/52; G03F 7/09; H01J 37/32

(52) U.S. Cl. CPC G03F 7/167; C23C 16/26; C23C 16/45536; C23C 16/45553; C23C 16/52; G03F 7/094; H01J 37/32357; H01J 37/3244; H01J 37/32733; H01J 37/32091; H01J 37/321; H01J 2237/332

(57) ABSTRACT

Methods, related structures, and related systems are provided for lithography, particularly extreme ultraviolet (EUV) lithography. Presently disclosed methods can comprise forming a carbon underlayer having a high sp3 carbon content. Presently disclosed methods can comprise forming a carbon underlayer by a deposition process that comprises continually generating a plasma and providing a precursor in a sequence of discrete pulses.

### CROSS-REFERENCE TO RELATED APPLICATION(S)

This application claims the benefit of U.S. Provisional Application 63/658,684 filed on Jun. 11, 2024, the entire contents of which are incorporated herein by reference.

### FIELD

The present disclosure is in the field of integrated circuit manufacturing, especially in the field of lithography.

### BACKGROUND

Compared to previous ultraviolet (UV) lithography methods, EUV lithography resolution is improved through decreased wavelength which also increases the photon energy and therefore energy consumption is greatly increased. To reduce the dose, either the photon flux or the exposure time needs to be decreased, both of which reduces the total number of photons hitting the lithography resists to very low amounts. Moreover, high energy EUV photons are more difficult to absorb by most materials, exaggerating the issue of the low photon count. With such a low number of photons absorbed by the resist, it is difficult to obtain a good quality lithography structure due to the photon shot noise effect, especially at the small structure sizes being pursued. Therefore, the key to practically decreasing dose is to increase the useful effect of the limited photons received.

EUV resists are being continuously improved to increase the material absorption of each photon, and increased the number of electrons produced per photon. Absorption is often improved by inserting EUV absorbing materials into the lithography structure which produces excited electrons, and the number of secondary electrons is increased by creating electron cascades to produce many lower energy electrons to initiate chemical changes in the resist. Current resists have been optimized to maximize these effects and absorb most of the photons. However, there remains a need for further dose lowering.

Amorphous carbon layers are used in lithography, e.g., EUV lithography. These are applied using high-through methods with a high growth rate such as one or more of spin coating, flowable deposition, and plasma-enhanced chemical vapor deposition. Such methods yield hard masks that do not offer a dose reduction effect for EUV lithography. “Dose” refers to the photon energy needed for fully developing a resist. “Dose reduction” refers to a reduction of the required dose for a particular lithography solution compared to a reference.

### SUMMARY OF THE DISCLOSURE

Described herein is a system that is constructed and arranged for forming an underlayer for lithographic patterning, the system comprising a reaction chamber comprising a substrate support that is constructed and arranged for supporting a substrate; a substrate moving robot constructed and arranged for positioning the substrate on the substrate support; the substrate support being constructed and arranged for supporting a substrate; a plasma gas conduit constructed and arranged for providing a plasma gas from a plasma gas source that comprises the plasma gas to the reaction chamber; a precursor conduit constructed and arranged for providing a precursor from a precursor source that comprises the precursor to the reaction chamber; a plasma generator constructed and arranged for generating a plasma in the reaction chamber; and, a process controller that is constructed and arranged for causing the system to execute a deposition process, the deposition process comprising providing a plasma gas to the reaction chamber; continuously generating a plasma in the reaction chamber by means of the plasma generator and the plasma gas; and, while continuously generating a plasma in the reaction chamber, providing a precursor to the reaction chamber in a sequence of discrete precursor pulses; wherein the underlayer comprises amorphous carbon.

In some embodiments, the plasma generator comprises an inductively coupled plasma source.

In some embodiments, the plasma generator comprises a capacitive plasma source.

Further described is a method of forming an underlayer for lithographic patterning, the method comprising providing a substrate to a reaction chamber; executing a deposition process that comprises providing a plasma gas to the reaction chamber; continuously generating a plasma in the reaction chamber by means of the plasma gas; and, while continuously generating a plasma in the reaction chamber, providing a precursor to the reaction chamber in a sequence of discrete precursor pulses; wherein the underlayer comprises amorphous carbon.

In some embodiments, the precursor comprises an organic compound.

In some embodiments, the organic compound comprises a hydrocarbon.

In some embodiments, the precursor comprises an aromatic compound.

In some embodiments, the aromatic compound is selected from the list consisting of benzene, alkylbenzene, toluene, ethylbenzene, xylene, durene, aniline, phenol, benzoic acid, biphenyl, mesitylene, styrene, toluidine, toluic acid, cresol, and naphthalene.

In some embodiments, the aromatic compound comprises 1,2,4-trimethylbenzene.

In some embodiments, the precursor comprises an alkane.

In some embodiments, the precursor comprises octane.

In some embodiments, the plasma gas comprises a noble gas.

In some embodiments, the plasma gas further comprises hydrogen.

In some embodiments, the underlayer substantially consists of amorphous carbon.

In some embodiments, the deposition process results in an initial underlayer having an initial sp3 carbon content, wherein the deposition process is followed by subjecting the substrate to a treatment step, the treatment step resulting in a treated underlayer having a treated sp3 carbon content, the treated sp3 carbon content being larger than the initial sp3 carbon content.

In some embodiments, the treatment step comprises a plasma treatment step that comprises generating a treatment plasma, and exposing the substrate to one or more active treatment species that were generated in the treatment plasma.

In some embodiments, the treatment plasma comprises one or more of an argon plasma and an oxygen plasma.

In some embodiments, ones from the sequence of discrete precursor pulses comprise a plurality of micro precursor pulses.

Further described herein is a method of forming an underlayer for lithographic patterning, the method comprising providing a substrate to a reaction chamber; and, executing a deposition process that comprises providing a plasma gas; continuously generating a plasma by means of the plasma gas to generate active species; continually exposing the substrate to the active species; and, while continuously generating the plasma, providing a precursor to the reaction chamber in a sequence of discrete precursor pulses; wherein the underlayer comprises amorphous carbon.

In some embodiments, the plasma gas is provided to a remote plasma unit, the remote plasma unit being operationally connected to the reaction chamber via an active species duct to continuously provide active species to the reaction chamber.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 shows an embodiment of a system 100.

FIG. 2 and FIG. 3 show embodiments of methods 200, 300.

FIG. 4 shows an embodiment of a structure 400.

FIG. 5 and FIG. 6 show embodiments of systems 500, 600.

FIG. 7 illustrates an embodiment of a deposition process.

FIG. 8 and FIG. 9 illustrate embodiments of systems 800, 900.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide. In some embodiments, the substrate can have an OH termination. The OH termination can occur natively, e.g., it can occur through atmospheric oxidation, or the OH termination can be provided intentionally, e.g., by subjecting the substrate to a plasma treatment.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the methods of the disclosure and their best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It shall be understood that tBu stands for tert-butyl, and that Me stands for methyl.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

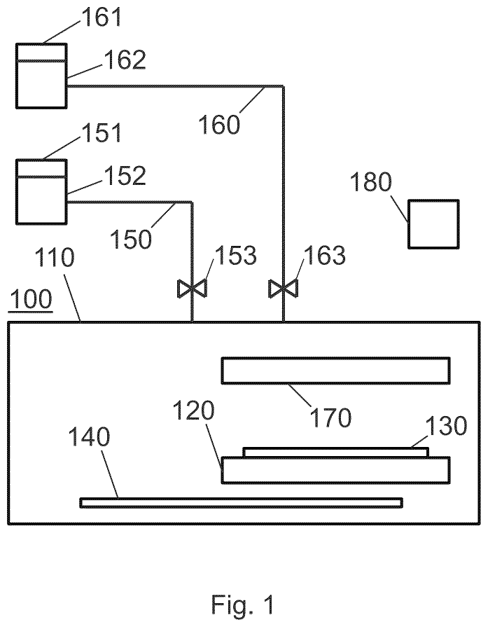

Referring to FIG. 1, described herein, is an embodiment of a system 100. The system 100 can be constructed and arranged for forming an underlayer for lithographic patterning. The underlayer can comprise amorphous carbon. The system 100 comprises a reaction chamber 110. The reaction chamber comprises a substrate support 120. The substrate support is constructed and arranged for supporting a substrate 130. The system 100 further comprises a substrate moving robot 140. The substrate moving robot 140 is constructed and arranged for positioning the substrate 130 on the substrate support 120. The system 100 further comprises a plasma gas conduit 150. The plasma gas conduit 150 is constructed and arranged for providing a plasma gas 152 from a plasma gas source 151 that comprises the plasma gas 152 to the reaction chamber 110. The plasma gas conduit 150 can be disposed with a plasma gas conduit valve 153 that is constructed and arranged for closing and opening the plasma gas conduit. The system 100 further comprises a precursor conduit 160. The precursor conduit 160 is constructed and arranged for providing a precursor 162 from a precursor source 161 that comprises the precursor 162 to the reaction chamber 110. The precursor conduit 160 can be disposed with a precursor conduit valve 163 that is constructed and arranged for closing and opening the precursor conduit. The system 100 further comprises a plasma generator 170. The plasma generator 170 is constructed and arranged for generating a plasma in the reaction chamber 110. The system 100 further comprises a process controller 180. The process controller 180 is constructed and arranged to cause the system to execute a deposition process.

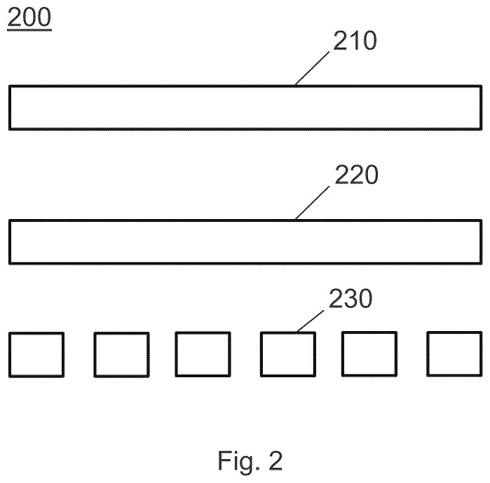

An embodiment of such a deposition process 200 is described with reference to FIG. 2. The deposition process 200 comprises providing 210 a plasma gas to the reaction chamber 110. Suitably, the plasma gas can be provided continuously to the reaction chamber 110. The deposition process 200 further comprises continuously generating 220 a plasma in the reaction chamber 110 by means of the plasma generator 170 and the plasma gas 152. The deposition process 200 further comprises, while continuously generating a plasma in the reaction chamber, providing 230 a precursor to the reaction chamber in a sequence of discrete precursor pulses.

Further described herein is an embodiment method of forming an underlayer for lithographic patterning. The method comprises providing a substrate to a reaction chamber. The method further comprises providing a plasma gas. The method further comprises continuously generating a plasma by means of the plasma gas to generate active species. The method further comprises continually exposing the substrate to the active species. The method further comprises, while continuously generating the plasma, providing a precursor to the reaction chamber in a sequence of discrete precursor pulses. In some embodiments, the underlayer comprises amorphous carbon. For example, such a method can be performed in, or by means of, a system as described herein.

Advantageously, methods according to embodiments of the present disclosure can offer dose reduction for EUV lithography. Additionally, methods according to embodiments of the present disclosure can provide carbon underlayers that have more sp3 carbon than sp2 carbon. In some embodiments, methods according to embodiments of the present disclosure can advantageously offer a growth rate of less than 1 nm/second.

In some embodiments, the plasma gas is provided to a remote plasma unit. The remote plasma unit can be operationally connected to the reaction chamber via an active species duct to continuously provide active species to the reaction chamber.

In some embodiments, ones from the sequence of discrete precursor pulses comprise a plurality of micro precursor pulses. In other words, a precursor pulse can comprise a sequence of micro precursor pulses in which precursor is provided, which are separated by moments during which precursor flow is stopped.

Advantageously, systems and methods according to embodiments of the present disclosure can offer dose reduction, i.e., they allow forming a photolithographic pattern with fewer photons compared to a reference. For example, during EUV exposure, metal centers may absorb EUV radiation. Thus, photoelectrons may be generated. Cascading photoelectrons may generate primary and secondary electrons. Secondary electrons may break radiation-sensitive ligands away from metal centers. An underlayer formed by means of an embodiment of the present disclosure may increase secondary electron flow to a resist. When exposed resist is exposed to air, broken ligands may react with at least one of H₂O and O₂ in air to form hydroxy groups. When the exposed resist is then subjected to a heat treatment, e.g., using a post exposure bake, hydroxy groups may condensate to form metal oxide. Unexposed resist may then be removed using a developer to form a pattern.

Without the subject matter of the present disclosure being bound by any particular theory or mode of operation, it is noted that dose reduction can occur during through a variety of mechanisms. For example, for extreme ultraviolet (EUV) lithography, dose reduction can occur through effects during exposure, or during a post exposure bake, or during resist development, or through a combination of various effects.

In some embodiments, the plasma generator 170 comprises an inductively coupled plasma source. In such embodiments, the plasma can comprise an inductively coupled plasma (ICP).

In some embodiments, the plasma generator comprises a capacitive plasma source. In such embodiments, the plasma can comprise a capacitively coupled plasma (CCP).

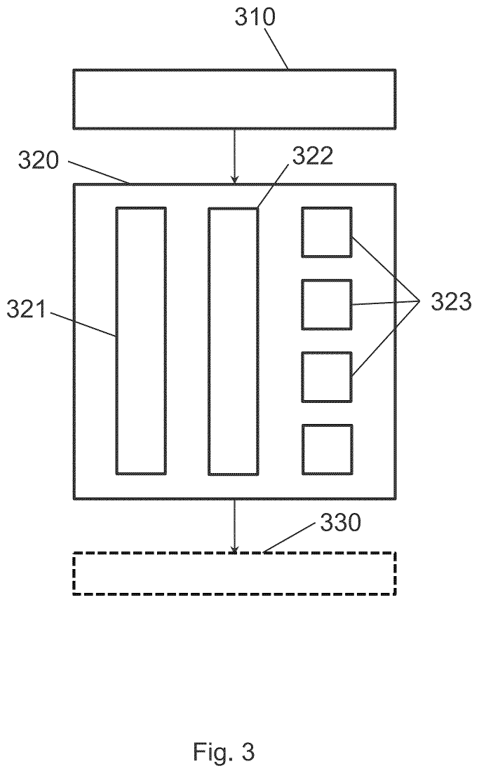

Referring to FIG. 3, described is an embodiment of a method 300 that comprises providing 310 a substrate to a reaction chamber. The method further comprises executing a deposition process 320. The deposition process 320 comprises providing 321 a plasma gas to the reaction chamber. The deposition process 320 further comprises generating 322 a plasma in the reaction chamber by means of the plasma gas. The deposition process 320 further comprises providing 323, while continuously generating a plasma in the reaction chamber, a precursor to the reaction chamber in a sequence of discrete precursor pulses. It shall be understood that the underlayer comprises amorphous carbon.

In some embodiments, an underlayer may be treated 330 after it has been formed. Indeed, an underlayer can be subjected to a treatment step such as an anneal, such as a forming gas anneal, e.g. at a temperature of at least 75° C. to at most 700° C., or of at least 300° C. to at most 600° C., or of at least 200° C. to at most 500° C. A treatment step can advantageously increase the underlayer's sp3 content. Thus, in some embodiments, the deposition process results in an initial underlayer that has an initial sp3 carbon content. The deposition process is followed by subjecting the substrate to a treatment step. The treatment step results in a treated underlayer. The treated underlayer has a treated sp3 carbon content. The treated sp3 carbon content is larger than the initial sp3 carbon content.

In some embodiments, the anneal occurs directly after deposition, without any intervening steps. In some embodiments, the anneal occurs after one or more intervening steps have been executed. A sequence of intervening steps can include exposing the substrate to EUV light through a mask and subjecting the substrate to a post exposure bake.

In some embodiments, the treatment can comprise exposing the substrate to a treatment precursor. In some embodiments, the treatment can comprise exposing the substrate to a plasma that employs a plasma gas, i.e., a treatment plasma gas, which comprises a treatment precursor. In some embodiments, exposing the substrate to at least one of a plasma and a treatment precursor can occur at a temperature which is the same as the temperature at which the underlayer is deposited. Alternatively, exposing the substrate to at least one of a plasma and a treatment precursor can occur at a different temperature. For example, exposing the substrate to at least one of a plasma and a treatment precursor can occur at a temperature of at least 75° C. to at most 700° C., or of at least 300° C. to at most 600° C., or of at least 200° C. to at most 500° C.

In some embodiments, the deposition process results in an initial underlayer that has an initial sp3 carbon content, and the deposition process can be followed by subjecting the substrate to a treatment step. The treatment step can result in a treated underlayer that has a treated sp3 carbon content. The treated sp3 carbon content can be larger than the initial sp3 carbon content.

In some embodiments, the treatment step comprises a plasma treatment step that comprises generating a treatment plasma. The treatment step can comprise exposing the substrate to one or more active treatment species that were generated in the treatment plasma.

In some embodiments, the treatment plasma comprises one or more of an argon plasma and an oxygen plasma.

In some embodiments, the treatment step can be carried out in-situ. In some embodiments, the treatment step can be carried out in the same reaction chamber as the deposition process. In some embodiments, the treatment step can be carried out in a different reaction chamber, a treatment reaction chamber, that is comprised in a cluster system that also comprises a deposition reaction chamber in which the deposition process is carried out. Thus, the deposition process and the treatment step can be sequentially carried out without any intervening vacuum break. For example, the substrate is not exposed to pressures higher than 100 Torr, or 10 Torr, or 1 Torr during transfer between deposition reaction chamber and treatment reaction chamber.

Advantageously, a treatment step as disclosed herein can be employed for tuning adhesion of resist to the underlayer, such that resist can be easily removed without causing pattern collapse.

In some embodiments, the treatment step comprises a plasma treatment step that comprises generating a treatment plasma that employs a treatment plasma gas. The plasma treatment step can comprise exposing the substrate to one or more active treatment species. Advantageously, a treatment can improve, i.e., reduce critical dimensions, i.e., smaller features can be printed without defects, i.e., pattern collapse. In some embodiments, the treatment plasma gas comprises a noble gas and optionally hydrogen. Additionally, or alternatively, the noble gas can comprise one or more of an oxygen reactant, a nitrogen reactant, a boron reactant, and a carbon reactant. Suitable oxygen reactants can be selected from O₂, O₃, H₂O, H₂O₂, N₂O, NO, NO₂, and NO₃. Suitable nitrogen reactants can be selected from N₂, NH₃, and N₂H₂. Suitable carbon reactants can comprise hydrocarbons such as alkanes such as CH₄, formic acid, isopropanol. Suitable boron reactants can comprise borohydrides such as B₂H₆, B₃H₆N₃, Suitable sulfur reactants can comprise hydrogen sulfide (H₂S), Carbon disulfide (CS₂), Sulfur(S). Suitable phosphorus reactants can comprise Phosphine (PH₃), white phosphorus. In some embodiments, the treatment plasma gas comprises a noble gas and an SiOC precursor. In some embodiments, the precursor comprises Si and C. In some embodiments, the precursor comprises a Si—C bond. In some embodiments, the precursor comprises an alkyl, alkenyl, alkynyl, or aryl group attached to silicon. In some embodiments, the precursor comprises an alkylamino group attached to Si. In some embodiments, the alkylamino is selected from —NMe₂, —NEt₂, —NEtMe, —NHtBu, —N(iPr)₂, —N(sBu)₂, —N(SiMe₃)₂, —N(SiEt₃)₂. In some embodiments, the precursor comprises an alkoxy group attached to Si. In some embodiments, the alkoxy group is selected from —OMe, —OEt, —OiPr, —OtBu, —OsBu, —OtPn, —OSiMe₃, or —OSiEt₃. In some embodiments, the SiOC precursor is selected from the list consisting of Dimethyldimethoxysilane, Tetramethyldimethoxydisiloxane, (3-Methoxypropyl) trimethoxysilane, Bis(diethylamino) silane, hexamethyldisilazane, and Dimethyltrimethylsilylamine. In some embodiments, the SiOC precursor is selected from the following: SiH(NMe₂)₃, Si(NMe₂)₄, Si(NEtMe)₄, SiCl(NMe₂)₃, SiH₂(NEt₂)₂, SiH₂(NHtBu)₂, SiH₃(N(iPr)₂), SiH₃(N(sBu)₂), Si₂(NHEt)₆, Si(OEt)₄, SiMe₃(NMe₂), SiMe₂(NMe₂)₂, SiH₂(NEtMe)₂.

For example, the treatment plasma gas can comprise O₂. For example, the treatment plasma gas can comprise H₂O, e.g., a plasma gas that substantially consists of Ar and H₂O. In some embodiments, the treatment plasma gas comprises O₂ and Ar. In some embodiments, the treatment plasma gas substantially consists of O₂ and Ar.

In some embodiments, the treatment comprises converting some or all of the sp2 carbon in an underlayer according to an embodiment of the present disclosure into sp3 carbon. Such a conversion can be achieved by one or more of introduction of a treatment precursor into a deposition process or as a post-deposition exposure step. For example, during deposition, the treatment precursor can be provided together with the precursor, or in alternating pulses, or continuously. In some embodiments, deposition steps and treatment steps are executed cyclically.

some embodiments, the treatment precursor comprises an alkylating, such as a strong alkylating agent.

In some embodiments, alkylating agents can include diiodo-substituted hydrocarbons such as diiodo alkanes such as diiodomethane, and 1,2-diiodoethane.

In some embodiments, the alkylating agent comprises a sulfonate such as methyl fluorosulfonate, methyl methanesulfonate, and methyl trifluoromethane sulfonate.

In some embodiments, the alkylating agent comprises a sulfate, such as an alkyl sulfate, such as dimethyl sulfate.

In some embodiments, the alkylating agent comprises a dihydrocarbyl carbonate such as a dialkyl carbonate such as dimethyl carbonate.

In some embodiments, the treatment precursor comprises a chemical capable of performing a transfer hydrogenation reaction.

For example, in some embodiments, the treatment precursor can comprise an organic acid such as formic acid.

In some embodiments, the treatment precursor comprises an alcohol, such as an alkyl alcohol, such as isopropanol.

In some embodiments, the treatment precursor comprises a cyclical hydrocarbon.

In some embodiments, the treatment precursor comprises a cyclical diene such as a substituted or unsubstituted hexadiene, such as a compound selected from the list consisting of 1,3-cyclohexadiene, 1,4-cyclohexadiene, and 1-methyl-1,4-cyclohexadiene.

In some embodiments, the treatment precursor comprises one or more aromatic rings. For example, the treatment precursor can comprise one or more of 9,10-dihydroanthracene or hydroquinone.

In some embodiments, the treatment precursor can comprise one or more of hydrazine and a hydrazine derivative. For example, the treatment precursor can be selected from the list consisting of hydrazine, dimethylhydrazine, and tert-butylhydrazine.

In some embodiments, the treatment precursor can comprise a dihydrocarbyl hydroxylamine, such as a dialkyl hydroxylamine, such as diethyl hydroxylamine.

In some embodiments, the treatment precursor comprises a diimide.

In some embodiments, the treatment comprises annealing the substrate. In some embodiments the substrate is thermally annealed for a period of about 1 to about 15 minutes. In some embodiments the substrate is thermally annealed at a temperature of about 200 to about 500° C. In some embodiments the thermal anneal step comprises two or more steps in which the substrate is thermally annealed for a first period of time at a first temperature and then thermally annealed for a second period of time at a second temperature.

In some embodiments, the treatment comprises exposing the underlayer to reactive species generated from plasma, in particular a treatment plasma. For example, reactive species generated from hydrogen- and argon-comprising plasma can be used. The underlayer may be exposed to plasma from about 0.1 seconds to about 1 minute, such as from about 1 second to about 30 seconds, or from about 5 seconds to about 30 seconds, or for about 1 second to about 15 seconds, or from about 3 seconds to about 20 seconds, for example for about 5 seconds, for about 10 seconds, for about 20 seconds or for about 30 seconds. A plasma power of at least about 20 W, or at least about 50 W, from about 20 W to about 100 W, such as 30 W, 50 W or 70 W, may be used. The suitable plasma power and duration of the plasma exposure may be determined experimentally.

In some embodiments, the treatment step comprises exposing the underlayer to electromagnetic radiation, such as one or more of microwaves, infrared radiation, visible light, ultraviolet light, or extreme ultraviolet light, and X-rays.

In some embodiments, forming an underlayer comprises executing a plurality of super cycles. The ones from the plurality of super cycle comprise a deposition process and a treatment step. The deposition process and the treatment step can be executed in the same reaction chamber or in different reaction chambers comprised in the same vacuum system. The deposition process can comprise a deposition process as described elsewhere herein. The treatment step can comprise a treatment as described elsewhere herein. Advantageously, performing such super cycles can yield an underlayer with a particularly high sp3 carbon content.

In some embodiments, the precursor comprises an organic compound. In some embodiments, the organic compound comprises a hydrocarbon. In some embodiments, the precursor comprises an aromatic compound. In some embodiments, the aromatic compound is selected from the list consisting of benzene, alkylbenzene, toluene, ethylbenzene, xylene, durene, aniline, phenol, benzoic acid, biphenyl, mesitylene, styrene, toluidine, toluic acid, cresol, and naphthalene. In some embodiments, the aromatic compound comprises 1,2,4-trimethylbenzene. In some embodiments, the precursor comprises an alkane. In some embodiments, the precursor comprises octane. In some embodiments, the precursor comprises an aromatic compound.

In some embodiments, the precursor comprises a cyclic compound selected from the list consisting of a substituted or unsubstituted cyclic diene. Examples of unsubstituted cyclic dienes include 1,3-cyclooctadiene and 1,3-cyclohexadiene. Examples of substituted cyclic dienes include alkyl-substituted cyclic dienes such as methyl cyclohexadiene, terpinene, phellandrene. Other examples of substituted cyclic dienes include alkyl- and alkenyl-substituted cyclic dienes such as limonene.

In some embodiments, the precursor comprises a multi-ring hydrocarbon such as dicyclopentadiene

In some embodiments, the precursor comprises a branched alkene such as myrcene, 2-methyl-2-butene, 2,3-dimethyl-2-butene, and 2,3-dimethyl-1,3-butadiene.

In some embodiments, the precursor is selected from the list consisting of benzene, alkylbenzene, toluene, ethylbenzene, xylene, durene, aniline, phenol, benzoic acid, biphenyl, mesitylene, styrene, toluidine, toluic acid, cresol, and naphthalene. In some embodiments, the precursor is selected from the list consisting of o-xylene, m-xylene, p-xylene. Same applies for toluic acid and cresol.

In some embodiments, the precursor comprises an alkylbenzene. In some embodiments, the alkylbenzene comprises trimethylbenzene. In some embodiments, the alkylbenzene comprises 1,2,4-trimethylbenzene.

In some embodiments, the precursor comprises a hydrocarbon. In some embodiments, the precursor comprises an alkane. In some embodiments, the precursor comprises a linear alkane. In some embodiments, the precursor comprises a branched alkane. In some embodiments, the precursor comprises one or more of methane, ethane, propane, butane, pentane, hexane, heptane, octane, nonane, and decane.

In some embodiments, the precursor comprises an aliphatic hydrocarbon.

In some embodiments, the precursor comprises bicyclo[2.2.2]octane. In some embodiments, the bicyclo[2.2.2]octane comprises one or more reactive substituents, e.g., in the 1- or 1,4-positions. Suitable reactive substituents can be selected from the list consisting of —F, —Cl, —Br, —I, —OH, —CH₂OH, —NH₂, —CH₂NH₂, —PH₂, —CH₂PH₂, —CH₂SH, —SH, —CHO, —COOH, and —COCl.

In some embodiments, employing such a precursor can increase the sp3 carbon content in the underlayer.

In some embodiments, the precursor comprises cubane. In some embodiments, the cubane comprises one or more reactive substituents, e.g., in the 1- or 1,4-positions. Suitable reactive substituents can be selected from the list consisting of —F, —Cl, —Br, —I, —OH, —CH₂OH, —NH₂, —CH₂NH₂, —PH₂, —CH₂PH₂, —CH₂SH, —SH, —CHO, —COOH, and —COCl. In some embodiments, employing such a precursor can increase the sp3 carbon content in the underlayer.

In some embodiments, the precursor comprises neopentane. In some embodiments, the neopentane comprises one or more reactive substituents on the terminal carbon atoms. Suitable reactive substituents can be selected from the list consisting of —F, —Cl, —Br, —I, —OH, —CH₂OH, —NH₂, —CH₂NH₂, —PH₂, —CH₂PH₂, —CH₂SH, —SH, —CHO, —COOH, and —COCl. In some embodiments, employing such a precursor can increase the sp3 carbon content in the underlayer.

In some embodiments, the precursor comprises a single arene ring. In some embodiments, the single arene ring comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises two or more fused arene rings, i.e., where each ring contains one or more carbon atoms that also are contained in another arene ring. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises a fullerene. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises a diene. The diene can comprise two carbon-carbon double bonds. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises an allene. In some embodiments, such a precursor comprises one or more reactive substituents. In some embodiments, the one or more reactive substituents can be selected from the list consisting of —F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises an alkyne. In some embodiments, such a precursor comprises one or more reactive substituents. In some embodiments, the one or more reactive substituents can be selected from the list consisting-F, —Cl, —Br, —I, —CH₂F, —CH₂Cl, —CH₂Br—, —CH₂I, —OH, —CH₂OH, —NH₂, —CH₂NH₂, —PH₂, —CH₂PH₂, —CH₂SH, —SH, —CHO, —COOH, and —COCl. In some embodiments, such a precursor can increase the sp2 carbon content in the underlayer.

In some embodiments, the precursor comprises a compound having the general formula

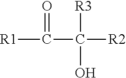

with R1, R2, and R3 being independently selected from H and hydrocarbyl. In some embodiments, R3 is H and R1 and R2 are independently selected from H and hydrocarbyl. In some embodiments, the hydrocarbyl is selected from alkyl, alkenyl, alkynyl, and aryl. In some embodiments, R3 is H, R1 is aryl, and R2 is alkyl. In some embodiments, R2 and R3 are equal. In some embodiments, R1 is aryl, and R2 and R3 are methyl. In some embodiments, the precursor comprises 2-hydroxy-2-methylpropiophenone.

In some embodiments, the precursor is selected from an alkylbenzene such as 1,2,4-trimethylbenze and an organic acid anhydride such as 2-hydroxy-2-methylpropiophenone.

In some embodiments, a deposition process according to an embodiment of the present disclosure can further comprise providing a dopant precursor. In some embodiments, the dopant precursor can be provided to the reaction chamber. Alternatively, the dopant precursor can be provided to a remote plasma source or elsewhere. In some embodiments, the dopant precursor is continuously provided to the reaction chamber. In some embodiments, the dopant precursor is provided to the reaction chamber in a plurality of discrete dopant precursor pulses. The dopant precursor comprises a dopant. Thus, an underlayer comprising the dopant can be formed. For example, the underlayer can comprise 0.1 to 1.0 atomic percent of the dopant, or 1.0 to 5.0 atomic percent of the dopant, or 5.0 to 20.0 atomic percent of the dopant.

In some embodiments, the dopant is selected from the list consisting of F, Ge, Cs, Bi, Sn, Hf, In, Sb, Te, Br, and I.

In some embodiments, the plasma gas comprises a noble gas such as He, Ne, Ar, Kr, and Xe. In some embodiments, the noble gas comprises argon.

In some embodiments, the plasma gas further comprises hydrogen. In some embodiments, the plasma gas comprises a noble gas and hydrogen. For example, the plasma gas can comprise argon and hydrogen.

In some embodiments, the plasma gas comprises Ar. In some embodiments, the plasma gas comprises He. In some embodiments, the plasma gas comprises Ar and H₂. In some embodiments, the plasma gas comprises Ar and N₂. In some embodiments, the plasma gas comprises Ar, H₂, and N₂. In some embodiments, the plasma gas comprises He and H₂. In some embodiments, the plasma gas comprises He, H₂, and N₂. In some embodiments, the plasma gas comprises Ar, H₂, and formic acid. In some embodiments, the plasma gas comprises Ar, N₂, and formic acid.

In some embodiments, the plasma can be a remote or an indirect plasma, and the substrate can be exposed to plasma-generated species that substantially consist of radicals. Any plasma gas as disclosed herein can be employed in a remote or indirect plasma configuration. In some embodiments, the plasma gas comprises a mixture of argon and H₂. When a remote or indirect plasma is employed, the substrate can be separated from the plasma by means of a mesh, a perforated plate, or the like.

In some embodiments, the plasma gas further comprises one or more reactive gases such as O₂, O₃, H₂O, NH₃, H₂, CO₂, N₂O, H₂S, formic acid, and acetone.

In some embodiments, a precursor pulse can comprise a plurality of subsequent micro pulses that comprise alternatingly exposing the substrate to a reactive species from the precursor and to reactive species from a plasma gas that does not comprise the precursor.

For example, when a capacitively coupled direct plasma is used, employing micro pulses can be used to control the number of ions reaching the substrate surface and thereby control the dangling bonds in the carbon film. This can, in turn, influence etch rate of the carbon film, and it can influence adhesion to a resist that is deposited onto that film. The resist can be a spin-on resist or a dry resist. Spin-on resists can be applied to a substrate via spin coating. Dry resists can be applied to a substrate via vapor phase deposition techniques such as molecular layer deposition. Additionally, or alternatively, micro pulses can be employed to control one or more of growth rate and composition of the carbon film.

In some embodiments, the underlayer substantially consists of amorphous carbon.

An underlayer according to an embodiment of the present disclosure can comprise carbon in various phases, crystal structures, and/or morphologies. For example, the carbon comprises one or more of cubic/diamond (sp3) carbon, hexagonal/Lonsdaleite (sp3) carbon, graphitic (sp2) carbon, a —C:H, nanocrystalline graphitic carbon (sp2), fullerene (sp2) carbon, and amorphous (sp3+sp2) carbon.

In some embodiments, an underlayer formed according to an embodiment of the present disclosure has a polar surface energy of 1-5 or 1-3 mJ/m² and a dispersive surface energy of 35-40 mJ/m². This should be compared to previous amorphous carbon hard masks which may have a polar surface energy of ˜17 mJ/m² and a dispersive surface energy of ˜38 mJ/m².

In some embodiments, at least 50 atomic percent of the carbon comprised in the underlayer is sp3 carbon. In some embodiments, at least 60, 70, 80, 90, 95, or 99 atomic percent of the carbon comprised in the underlayer is sp3 carbon.

In some embodiments, the underlayer comprises one or more of amorphous carbon, microcrystalline carbon, polycrystalline carbon, carbon-containing polymers, carbon-containing oligomers, and carbon-containing cross-linked resins.

Advantageously, underlayers formed using embodiments of methods according to the present disclosure exhibit good etch contrast with metalorganic resist. Advantageously, underlayers formed using embodiments of methods according to the present disclosure exhibit dose reduction. Advantageously, underlayers formed using embodiments of methods according to the present disclosure exhibit low line roughness.

In some embodiments, and underlayer as described herein comprises hydrogen, for example from at least 1 atomic percent hydrogen to at most 10 atomic percent hydrogen, or from at least 10 atomic percent hydrogen to at most 20 atomic percent hydrogen, or from at least 20 atomic percent hydrogen to at most 30 atomic percent hydrogen, or from at least 30 atomic percent hydrogen to at most 40 atomic percent hydrogen, or from at least 40 atomic percent hydrogen to at most 50 atomic percent hydrogen, or from at least 50 atomic percent hydrogen to at most 60 atomic percent hydrogen.

Advantageously, an underlayer as described herein can have a high sp3 carbon content and a relatively high hydrogen content.

In some embodiments, the underlayer substantially consists of amorphous carbon. Amorphous carbon can comprise non-crystalline carbon and hydrogen.

In some embodiments, the underlayer comprises at least 50 atomic percent carbon. In some embodiments, the underlayer comprises at least 60 atomic percent carbon. In some embodiments, the underlayer comprises at least 70 atomic percent carbon. In some embodiments, the underlayer comprises at least 80 atomic percent carbon. In some embodiments, the underlayer comprises at least 90 atomic percent carbon. In some embodiments, the underlayer comprises at least 95 atomic percent carbon. In some embodiments, the underlayer comprises at least 99 atomic percent carbon. In some embodiments, the underlayer substantially consists of carbon and hydrogen.

In some embodiments, the underlayer comprises from at least 20 atomic percent to at most 60 atomic percent hydrogen and from at least 40 atomic percent to at most 80 atomic percent carbon. In some embodiments, the underlayer comprises from at least 30 atomic percent to at most 50 atomic percent hydrogen and from at least 50 atomic percent to at most 70 atomic percent carbon.

In some embodiments, the underlayer comprises one or more elements that have a high capture cross section for extreme ultraviolet (EUV) radiation.

In some embodiments, the underlayer comprises tin (Sn). In some embodiments, the underlayer comprises an element selected from the list consisting of F, Ge, Hf, In, Sb, Sn, I, Te, Cs, and Bi.

In some embodiments, the underlayer has a thickness of at least 1 nm to at most 30 nm, or of at least 1 nm to at most 2 nm, or of at least 2 nm to at most 5 nm, or of at least 5 nm to at most 10 nm, or of at least 10 nm to at most 20 nm, or of at least 20 nm to at most 30 nm.

Further described herein is a structure that comprises a substrate, an underlayer overlying the substrate, and a photosensitive layer overlying the underlayer. The underlayer is formed by means of a method as described herein.

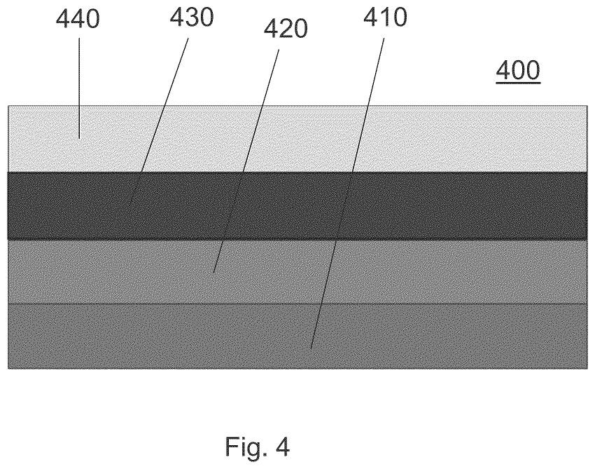

An exemplary structure 400 for EUV lithography is described referring to FIG. 4. The structure 400 comprises a substrate 410. The substrate 410 is covered with an ashable hard mask 420. The ashable hard mask 420 can comprise amorphous carbon that is deposited by means of plasma enhanced chemical vapor deposition and that comprises a relatively high concentration of sp2 hybridized carbon, e.g., more than 70 atomic percent sp2 hybridized carbon. On top of the ashable hard mask 420 lies an underlayer 430 according to an embodiment according to the present disclosure. On top of the underlayer 430 lies an EUV resist 440, e.g., a metalorganic resist.

Further described herein is a system that comprises a reaction chamber, a substrate support, and a controller that is constructed and arranged for causing the system to execute a method as described herein.

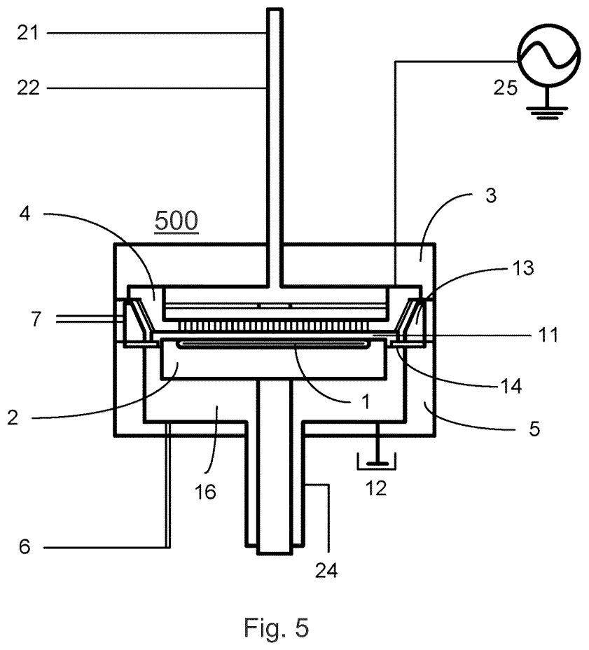

The presently provided methods may be executed in any suitable system, including in a system 500 as shown in FIG. 5. Similarly, the presently provided structures may be manufactured in any suitable system, including a reactor as shown in FIG. 5. FIG. 5 is a schematic view of an embodiment of a plasma-enhanced atomic layer deposition (PEALD) system, desirably in conjunction with controls programmed to conduct the sequences described below, usable in some embodiments of the present disclosure. In this figure, by providing a pair of electrically conductive flat-plate electrodes (2,4) in parallel and facing each other in the interior (11) (reaction zone) of a reaction chamber (3), applying RF power (e.g. at 13.56 MHz and/or 27 MHz) from a power source (25) to one side, and electrically grounding the other side (12), a plasma is excited between the electrodes. A temperature regulator may be provided in a lower stage (2), i.e., the lower electrode. A substrate (1) is placed thereon, and its temperature is kept constant at a given temperature. The upper electrode (4) can serve as a shower plate as well, and a reactant gas and/or a dilution gas, if any, as well as a precursor gas can be introduced into the reaction chamber (3) through a gas line (21) and a gas line (22), respectively, and through the upper electrode 4 (e.g., a shower plate). Additionally, in the reaction chamber (3), a circular duct (13) with an exhaust line (17) is provided, through which the gas in the interior (11) of the reaction chamber (3) is exhausted. Additionally, a transfer chamber (5) is disposed below the reaction chamber (3) and is provided with a gas seal line (24) to introduce seal gas into the interior (11) of the reaction chamber (3) via the interior (16) of the transfer chamber (5) wherein a separation plate (14) for separating the reaction zone and the transfer zone is provided. Note that a gate valve through which a wafer may be transferred into or from the transfer chamber (5) is omitted from this figure. The transfer chamber is also provided with an exhaust line (6). In some embodiments, depositing the underlayer and curing the underlayer is done in one and the same reaction chamber. In some embodiments, forming the underlayer and curing the underlayer is done in separate reaction chambers comprised in one and the same system.

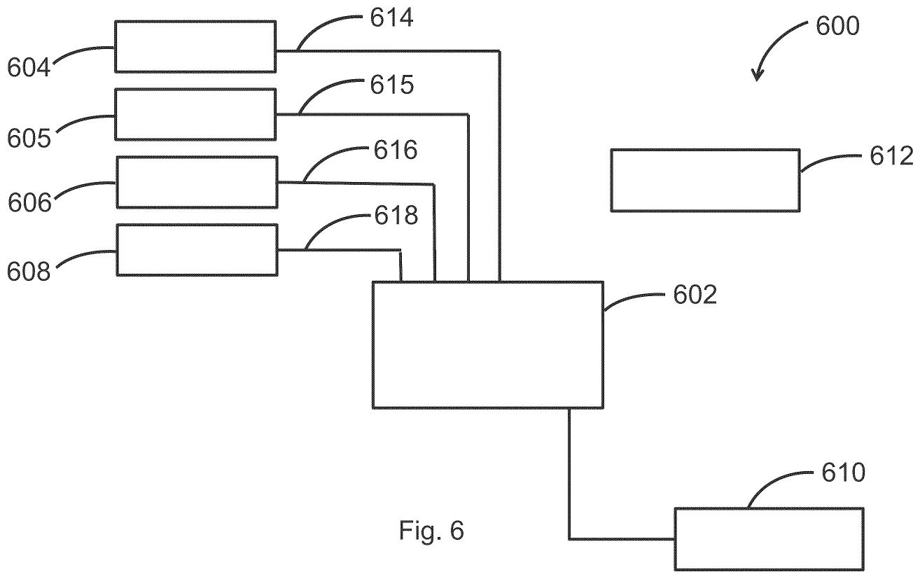

FIG. 6 illustrates another embodiment of a system 600 in accordance with exemplary embodiments of the disclosure. The system 600 can be configured to perform a method as described herein and/or form a structure or device portion as described herein. In the illustrated example, the system 600 includes one or more reaction chambers 602, a first precursor gas source 604, a reactant gas source 606, an optional further precursor source 608, an exhaust 610, and a controller 612. In some embodiments, the system further comprises at least one of a second precursor gas source (not shown) and a second dopant precursor gas source (not shown). The reaction chamber 602 can include an atomic layer deposition (ALD) reaction chamber.

The first precursor gas source 604 can include a vessel and one or more precursors as described herein-alone or mixed with one or more carrier (e.g., noble) gases. The reactant gas source 606 can include a vessel and one or more dopant precursors as described herein-alone or mixed with one or more carrier gases. The optional further precursor source 608 can include one or more further precursors or reactants as described herein.

Although illustrated with four gas sources 604-608, the system 600 can include any suitable number of gas sources. The gas sources 604-608 can be coupled to the reaction chamber 602 via the lines 614-618, which can each include flow controllers, valves, heaters, and the like. The exhaust 610 can include one or more vacuum pumps.

The controller 612 includes electronic circuitry and software to selectively operate valves, manifolds, heaters, pumps, and other components included in the system 600. Such circuitry and components operate to introduce precursors, reactants, and purge gases from the respective sources 604-608. The controller 612 can control timing of gas pulse sequences, temperature of the substrate and/or reaction chamber, pressure within the reaction chamber, and various other operations to provide proper operation of the system 600. The controller 612 can include control software to electrically or pneumatically control valves to control flow of precursors, reactants, and purge gases into and out of the reaction chamber 602. The controller 612 can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system 600 are possible, including different numbers and kinds of precursor and oxygen reactant sources and optionally further including purge gas sources. Further, it will be appreciated that there are many arrangements of valves, conduits, precursor sources, and purge gas sources that may be used to accomplish the goal of selectively feeding gases into the reaction chamber 602. Further, as a schematic representation of a system, many components have been omitted for simplicity of illustration, and such components may include, for example, various valves, manifolds, purifiers, heaters, containers, vents, and/or bypasses.

During operation of the system 600, substrates, such as semiconductor wafers (not illustrated), are transferred from, e.g., a substrate handling system to the reaction chamber 602. Once the substrate(s) are transferred to the reaction chamber 602, one or more gases from the gas sources 604-608, such as precursors, reactants, carrier gases, and/or purge gases, are introduced into the reaction chamber 602.

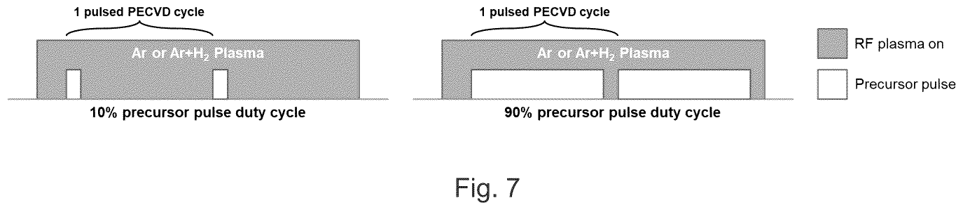

Referring to FIG. 7, described herein is an embodiment of a deposition process. The plasma gas comprises one or more of N₂ and a noble gas such as Ar and He. Optionally, the plasma gas further comprises one or more reactive gases such as H₂, O₂, O₃, H₂O, and NH₃, CO₂, N₂O, H₂S, formic acid, and acetone. The precursor comprises 1,2,4-Trimethylbenzene. The precursor can be pulsed intermittently. The time between the start point of subsequent pulses is called cycle time. The cycle time can be from at least 0.1 seconds to at most 100 seconds, e.g., 0.5 sec, 1 sec, 5 sec, 10 sec, etc. The ratio of precursor pulse duration to cycle time is called precursor duty cycle. The precursor duty cycle can be, for example, from at least 1% to at most 99%, for example 10%, 50%, or 90%. A capacitive direct plasma can be used, with a plasma power of 50-500 W that operates at a frequency between 100 kHz and 100 MHz. Pressure in the reaction chamber can be 150-2000 Pa. The plasma gas can comprise one or more of H₂, Ar, He, N₂. Suitable substrate temperatures include temperatures form at least 50° C. to at most 200° C., such as temperatures from at least 75° C. to at most 150° C. Experimental results advantageously indicated lower critical dimensions and lower lateral edge roughness when an underlayer according to an embodiment of the present disclosure was integrated in a structure according to FIG. 4, compared to a reference underlayer based on spin-on glass. When an underlayer was treated with an O₂ plasma for 2 seconds, adhesion to metalorganic resist was improved such that patterns with smaller critical dimensions could be printed without defects, i.e., pattern collapse.

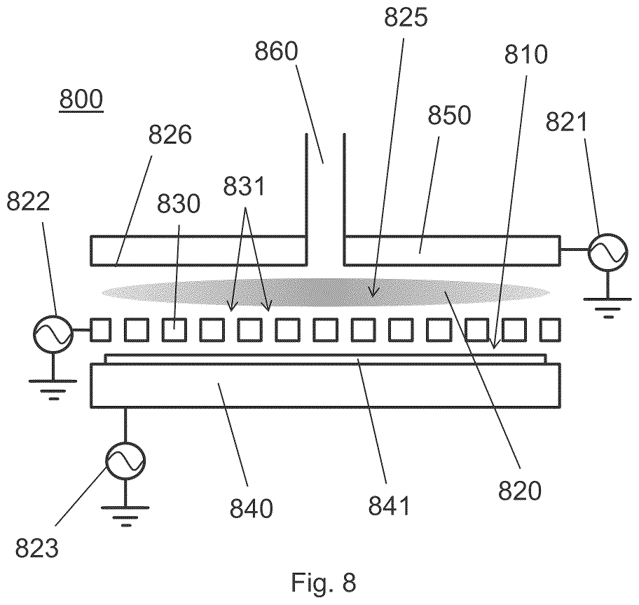

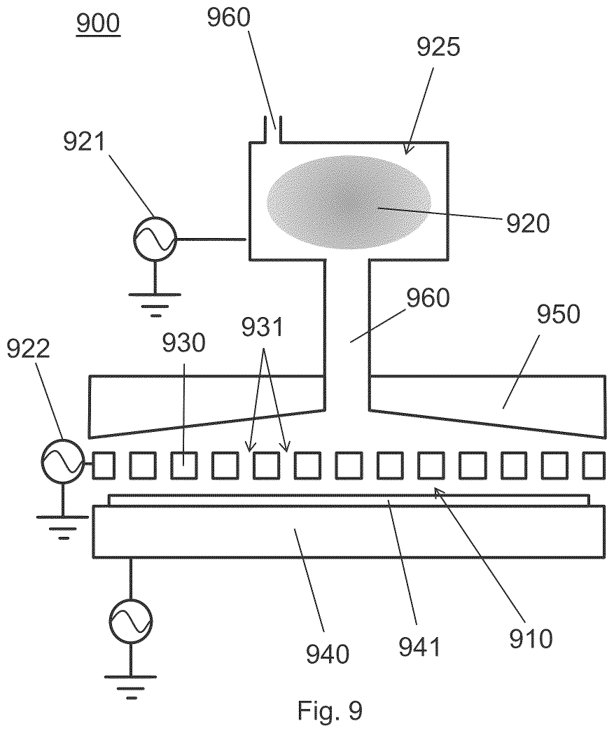

Referring to FIG. 8, described is a schematic representation an embodiment of a sub-system 800 as described herein. It can be used, for example, for forming an underlayer as described herein. Additionally, or alternatively, it can be employed for etching one or more of a gap filling fluid and a material layer. The configuration of FIG. 9 can be described as an indirect plasma system. The sub-system 800 comprises a reaction chamber 810 which is separated from a plasma generation space 825 in which a plasma 820 is generated. In particular, the reaction chamber 810 is separated from the plasma generation space 825 by a showerhead injector, and the plasma 820 is generated between the showerhead injector 830 and a plasma generation space ceiling 826.

In the configuration shown, the sub-system 800 comprises three alternating current (AC) power sources: a high frequency power source 821 and two low frequency power sources 822,823: a first low frequency power source 822 and a second low frequency power source 823. In the configuration shown, the high frequency power source 821 supplies radio frequency (RF) power to the plasma generation space ceiling, the first low frequency power source 822 supplies an alternating current signal to the showerhead injector 830, and the second low frequency power source 823 supplies an alternating current signal to the substrate support 840. A substrate 841 is provided on the substrate support 840. The radio frequency power can be provided, for example, at a frequency of 13.56 MHz or higher. The low frequency alternating current signal of the first and second low frequency power sources 822,823 can be provided, for example, at a frequency of 2 MHz or lower.

Process gas comprising precursor, plasma gas, or both, can be provided through a gas line 860 that passes through the plasma generation space ceiling 826, to the plasma generation space 825. Active species such as ions and radicals generated by the plasma generation space 825 from the process gas pass through holes 831 in the showerhead injector 830 to the reaction chamber 810. Additionally, or alternatively, precursor can be provided directly to the reaction chamber 810.

FIG. 9 illustrates a schematic representation of another embodiment of a sub-system 900 as described herein. It can be used, for example, for forming an underlayer as described herein. The configuration of FIG. 9 can be described as a remote plasma system. The sub-system 900 comprises a reaction chamber 910 which is operationally connected to a remote plasma source 925 in which a plasma 920 is generated. Any sort of plasma source can be used as a remote plasma source 925, for example an inductively coupled plasma, a capacitively coupled plasma, or a microwave plasma.

In particular, active species are provided from the remote plasma source 925 to the reaction chamber 910 via an active species duct 960, to a conical distributor 950, through holes 931 in a shower plate injector 930, to the reaction chamber 910. Thus, active species can be provided to the reaction chamber in a uniform way.

In the configuration shown, the sub-system 900 comprises three alternating current (AC) power sources: a high frequency power source 921 and two low frequency power sources 922,923: a first low frequency power source 922 and a second low frequency power source 923. In the configuration shown, the high frequency power source 921 supplies radio frequency (RF) power to the plasma generation space ceiling, the first low frequency power source 922 supplies an alternating current signal to the showerhead shower plate injector 930, and the second low frequency power source 923 supplies an alternating current signal to the substrate support 940. A substrate 941 is provided on the substrate support 940. The radio frequency power can be provided, for example, at a frequency of 13.56 MHz or higher. The low frequency alternating current signal of the first and second low frequency power sources 922,923 can be provided, for example, at a frequency of 2 MHz or lower.

In some embodiments (not shown), an additional high frequency power source can be electrically connected to the substrate support. Thus, a direct plasma can be generated in the reaction chamber.

Process gas comprising precursor, reactant, or both, is provided to the remote plasma source 925 by means of the active species duct 960. Active species such as ions and radicals generated by the remote plasma source 925 from the process gas are guided to the reaction chamber 910.

What is claimed:

1. A system that is constructed and arranged for forming an underlayer for lithographic patterning, the system comprising:
a reaction chamber comprising a substrate support that is constructed and arranged for supporting a substrate;
a substrate moving robot constructed and arranged for positioning the substrate on the substrate support, the substrate support being constructed and arranged for supporting the substrate;
a plasma gas conduit constructed and arranged for providing a plasma gas from a plasma gas source that comprises the plasma gas to the reaction chamber;
a precursor conduit constructed and arranged for providing a precursor from a precursor source that comprises the precursor to the reaction chamber;
a plasma generator constructed and arranged for generating a plasma in the reaction chamber; and
a process controller that is constructed and arranged for causing the system to execute a deposition process, the deposition process comprising:
providing the plasma gas to the reaction chamber;
continuously generating the plasma in the reaction chamber by means of the plasma generator and the plasma gas; and while continuously generating the plasma in the reaction chamber, providing the precursor to the reaction chamber in a sequence of discrete precursor pulses,
wherein the underlayer comprises an amorphous carbon.

2. The system according to claim 1, wherein the plasma generator comprises an inductively coupled plasma source.

3. The system according to claim 1, wherein the plasma generator comprises a capacitive plasma source.

4. A method of forming an underlayer for lithographic patterning, the method comprising:
providing a substrate to a reaction chamber; and
executing a deposition process that comprises:
providing a plasma gas to the reaction chamber;
continuously generating a plasma in the reaction chamber by the plasma gas; and
while continuously generating the plasma in the reaction chamber, providing a precursor to the reaction chamber in a sequence of discrete precursor pulses,
wherein the underlayer comprises an amorphous carbon.

5. The method according to claim 4, wherein the precursor comprises an organic compound.

6. The method according to claim 5, wherein the organic compound comprises a hydrocarbon.

7. The method according to claim 6, wherein the precursor comprises an aromatic compound.

8. The method according to claim 7, wherein the aromatic compound is selected from a list consisting of benzene, alkylbenzene, toluene, ethylbenzene, xylene, durene, aniline, phenol, benzoic acid, biphenyl, mesitylene, styrene, toluidine, toluic acid, cresol, and naphthalene.

9. The method according to claim 7, wherein the aromatic compound comprises 1,2,4-trimethylbenzene.

10. The method according to claim 6, wherein the precursor comprises an alkane.

11. The method according to claim 6, wherein the precursor comprises an octane.

12. The method according to claim 4, wherein the plasma gas comprises a noble gas.

13. The method according to claim 12, wherein the plasma gas further comprises hydrogen.

14. The method according to claim 4, wherein the underlayer substantially consists of the amorphous carbon.

15. The method according to claim 4, wherein the deposition process results in an initial underlayer having an initial sp3 carbon content, wherein the deposition process is followed by subjecting the substrate to a treatment step, the treatment step resulting in a treated underlayer having a treated sp3 carbon content, the treated sp3 carbon content being larger than the initial sp3 carbon content.

16. The method according to claim 15, wherein the treatment step comprises a plasma treatment step that comprises generating a treatment plasma, and exposing the substrate to one or more active treatment species that were generated in the treatment plasma.

17. The method according to claim 16, wherein the treatment plasma comprises one or more of an argon plasma and an oxygen plasma.

18. The method according to claim 4, wherein ones from the sequence of discrete precursor pulses comprise a plurality of micro precursor pulses.

19. A method of forming an underlayer for lithographic patterning, the method comprising:
providing a substrate to a reaction chamber; and,
executing a deposition process that comprises:
providing a plasma gas;
continuously generating a plasma by the plasma gas to generate active species;
continually exposing the substrate to the active species; and
while continuously generating the plasma, providing a precursor to the reaction chamber in a sequence of discrete precursor pulses,
wherein the underlayer comprises an amorphous carbon.

20. The method according to claim 19, wherein the plasma gas is provided to a remote plasma unit, the remote plasma unit being operationally connected to the reaction chamber via an active species duct to continuously provide active species to the reaction chamber.
